(19) United States
(12) Patent Application Publication
(10) Pub. No.: US 2011/0068240 A1
(43) Pub. Date: Mar. 24, 2011

(54) INTERFACE CARD FIXING DEVICE

(75) Inventors: Chun Ying Yang, Taiwan (TW); Ying Chao Peng, Taiwan (TW)

(73) Assignee: Inventec Corporation

(21) Appl. No.: 12/562,379

(22) Filed: Sep. 18, 2009

(51) Int. Cl. H05K 7/12; H05K 7/16

(52) U.S. Cl. 248/221.11; 248/222.13

(57) ABSTRACT

An interface card fixing device for fixing an interface card in a case of a computer device is presented. The interface card fixing device includes a body and a pressing member. The body is fixed on the case, and has an accommodation slot, and a guiding slot crossing the accommodation slot. The interface card slides within the guiding slot to a combination position. A pivoting end of the pressing member is pivotally connected to the body, such that a pressing end of the pressing member relatively pivotally rotates to a pressing position, and is fixed in the accommodation slot. The pressing end and the pivoting end form an angle, so as to press against the interface card to maintain the interface card at the combination position.

### BACKGROUND OF THE INVENTION

1. Field of the Invention

The present invention relates to a fixing device, and more particularly to an interface card fixing device.

2. Related Art

Nowadays, with the continuous and vigorous development of technology and information, computer equipments have become popularized. For the computers equipments currently available on the market, no matter desktop computers, notebook computers, or servers, peripheral hardware systems used therein, such as a peripheral component interconnect card (PCI card), a video graphics array card (VGA card), and other external hardware devices, must be electrically connected to a main board, such that a computer host and the peripheral hardware systems communicate with each other and transmit signals to each other, thereby performing default functions of the peripheral hardware. In order to prevent an interface card from being loosened or detached by an external force, the interface card is fixed in a socket of the main board of the computer by a fixing method.

Currently, in order to fix interface cards in a server computer, an interface card bracket is disposed in a case of the server computer, such that a patch board including a plurality of interface card sockets is fixed in the bracket. Interface cards are fixed in the interface card bracket, and electrically connected to the interface card sockets. Then, the interface card bracket is locked and fixed at a predetermined position within the case by using screws, and the patch board is electrically connected to a main board, such that the interface cards are electrically connected to the main board.

However, when the interface card is mounted or removed, the screws need to be tightened or loosened and removed by using a hand tool, and since it takes time to tighten or loosen and remove the screws, more time is required to replace the interface card. Meanwhile, the screws easily fall onto the main board, causing the main board to be damaged due to short circuit. Since server computers of different types have different case sizes and different circuit configurations, the interface card bracket cannot be applied in server computers of different types, resulting in inconvenience in use and increased manufacturing cost.

In addition, U.S. Pat. No. 7,161,798 (hereafter referred to as Patent No. 798) discloses an expansion card retention apparatus, which includes a first retention bracket, a second retention bracket, and a rear panel. The rear panel defines a number of expansion slots, and the first retention bracket is rotatably fixed to the rear panel. The second retention bracket is fixed to the first retention bracket, and defines a number of flexible tongues. The expansion cards are thus fixed in the expansion slots.

Although Patent No. 798 can solve the problem resulting from the use of screws for locking and fixing the interface cards, Patent No. 798 only use a pressing element to directly press against a plurality of interface cards by surface contact, so as to fix the interface cards. If the computer device is severely shaken or impacted by an external force, the pressing element is easily loosened or detached from the interface cards, and thus can no longer press against the interface cards.

### SUMMARY OF THE INVENTION

In view of the above problems, the present invention is an interface card fixing device, so as to solve the problems that a conventional interface card fixing device cannot be applied in server computers of different types, and that since the conventional interface card fixing device only uses a single pressing element to directly press against a plurality of interface cards, the pressing element is easily loosened or detached from the interface cards by an external force, and thus can no longer press against the interface cards.

The present invention provides an interface card fixing device for fixing an interface card in a case of a computer device. The interface card fixing device comprises a body and a pressing member. The body is fixed on the case, and has at least one slide rail, an accommodation slot, and a guiding slot crossing the accommodation slot. The interface card slides within the guiding slot to a combination position. One end of the pressing member is a pivoting end, and the other end of the pressing member is a pressing end. The pivoting end is pivotally disposed in the slide rail, such that the pressing member moves along the slide rail, and the pressing end pivotally rotates between a releasing position and a pressing position.

When the pressing end pivotally rotates to the pressing position, the pressing end is fixed in the accommodation slot of the body, and presses against the interface card to maintain the interface card at the combination position. The pressing end and the pivoting end form an angle.

The present invention further provides an interface card fixing device for fixing an interface card in a case of a computer device. The interface card fixing device comprises a body and a pressing member. The body is fixed on the case. One end of the body is a first pivoting end, and the first pivoting end has an accommodation slot. The body has a guiding slot crossing the accommodation slot. The interface card slides within the guiding slot to a combination position. One end of the pressing member is a second pivoting end, and the other end of the pressing member is a pressing end. The second pivoting end is pivotally connected to the first pivoting end of the body, and the pressing end pivotally rotates between a releasing position and a pressing position.

When the pressing end pivotally rotates to the pressing position, the pressing end is fixed in the accommodation slot of the body, and presses against the interface card to maintain the interface card at the combination position. The pressing end and the second pivoting end form an angle.

The efficacy of the present invention lies in that, the interface card fixing device can be applied to assemble interface cards to computer devices of different types, the pressing end of the pressing member is fixed in the accommodation slot of the body, so as to interfere with the interface card, and the pressing end and the pivoting end of the pressing member form an angle, so as to stably press against the interface card to maintain the interface card at the combination position without being loosened or detached.

### BRIEF DESCRIPTION OF THE DRAWINGS

The present invention will become more fully understood from the detailed description given herein below for illustration only, and thus are not limitative of the present invention, and wherein:

FIG. 1A is an exploded view of an interface card fixing device according to a first embodiment of the present invention;

FIG. 1B is a schematic view of the interface card fixing device according to the first embodiment of the present invention;

FIG. 2 is an exploded view of the first embodiment of the present invention;

FIG. 3 is a schematic partially enlarged view of the first embodiment of the present invention in an assembled state;

FIG. 4 is a schematic partially enlarged view of the first embodiment of the present invention in an assembled state;

FIG. 5 is a plane side view of FIG. 4;

FIG. 6A is an exploded view of an interface card fixing device according to a second embodiment of the present invention;

FIG. 6B is a schematic view of the interface card fixing device according to the second embodiment of the present invention;

FIG. 7 is an exploded view of the second embodiment of the present invention;

FIG. 8 is a schematic partially enlarged view of the second embodiment of the present invention in an assembled state;

FIG. 9 is a schematic partially enlarged view of the second embodiment of the present invention in an assembled state; and

FIG. 10 is a plane side view of FIG. 9.

### DETAILED DESCRIPTION OF THE INVENTION

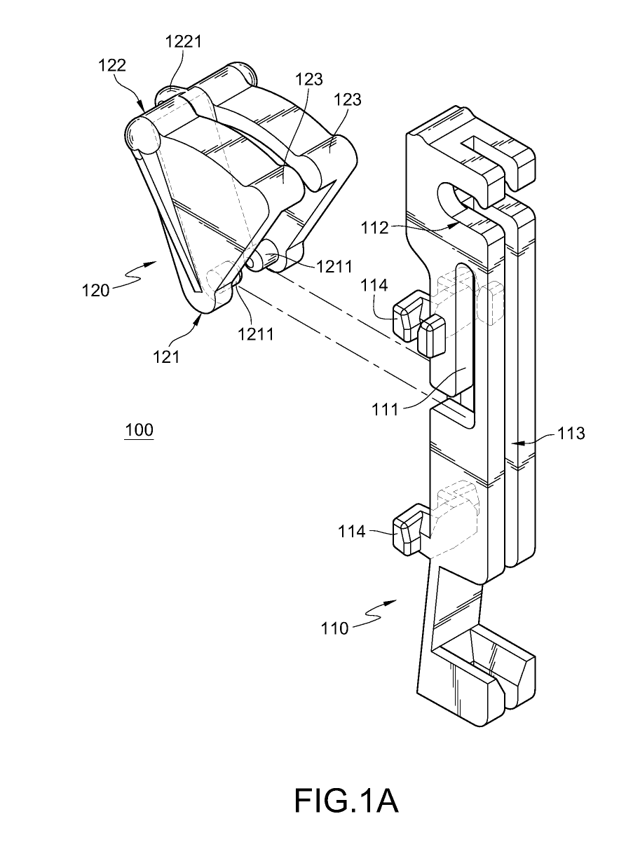

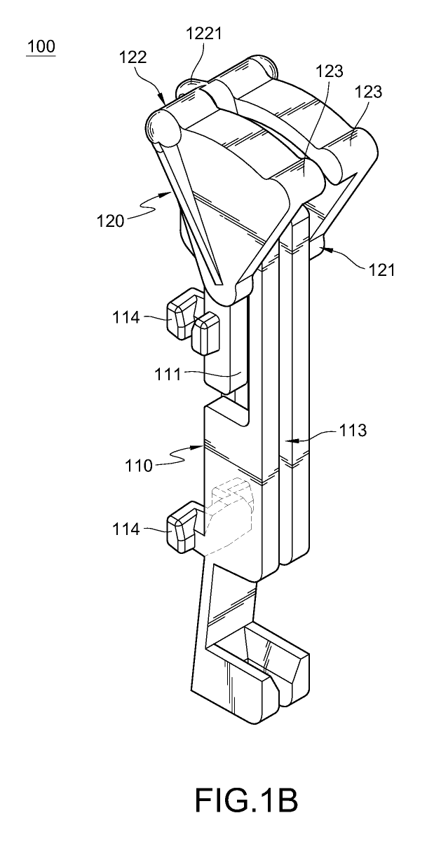

FIGS. 1A, 1B, and 2 are schematic three-dimensional views of a first embodiment of the present invention. An interface card fixing device 100 according to the first embodiment of the present invention is used for fixing an interface card 200 in a case 310 of a computer device 300. A plurality of interface cards 200 may be electrically disposed in the computer device 300, and the number of the interface card fixing device 100 is determined by the number of the interface card 200, such that the interface card fixing device 100 and the interface card 200 are combined in a one-to-one manner.

The interface card fixing device 100 according to the first embodiment of the present invention comprises a body 110 and a pressing member 120. The body 110 is designed as a bar-shaped structure, and has at least two hooks 114 on a side surface thereof. The hooks 114 are fastened into buckling holes 311 of the case 310, such that the body 110 is fixed on the case 310. It should be noted that, persons skilled in the art may also use other methods to combine the body 110 with the case 310, and the present invention is not limited to this embodiment.

Referring to FIGS. 1A and 1B, corresponding slide rails 111 are respectively formed on two opposite side edges of the body 110. One end of the body 110 further has an inwardly recessed accommodation slot 112, and the body 110 further has a guiding slot 113 crossing the accommodation slot 112 (that is, the guiding slot 113 is disposed along a major axis of the body 110), such that the accommodation slot 112 and the guiding slot 113 are disposed perpendicular to each other.

One end of the pressing member 120 is a pivoting end 121, and the other end of the pressing member 120 is a pressing end 122. Two opposite pivot shafts 1211 are protruded from inner wall surfaces of the pivoting end 121, and are respectively inserted into the two slide rails 111, such that the pressing member 120 is pivotally connected to the body 110, the pressing member 120 reciprocally moves along the slide rails 111 relative to the body 110, and the pressing end 122 slides on the body 110 along with the pressing member 120. In addition, the pressing member 120 further has two operating portions 123, such that a user may hold the operating portions 123 to enable the pressing member 120 to slide or pivotally rotate. The pressing end 122 of the pressing member 120 further has a stopping portion 1221.

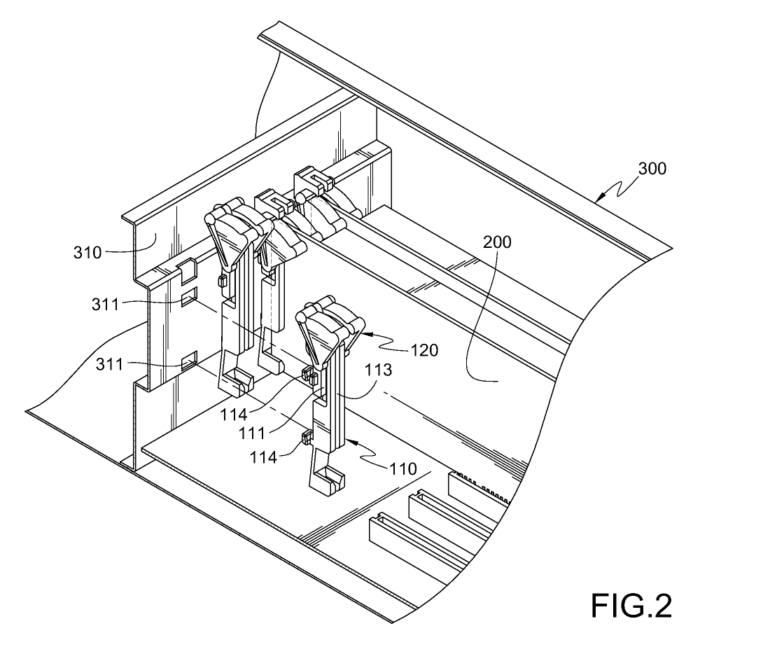

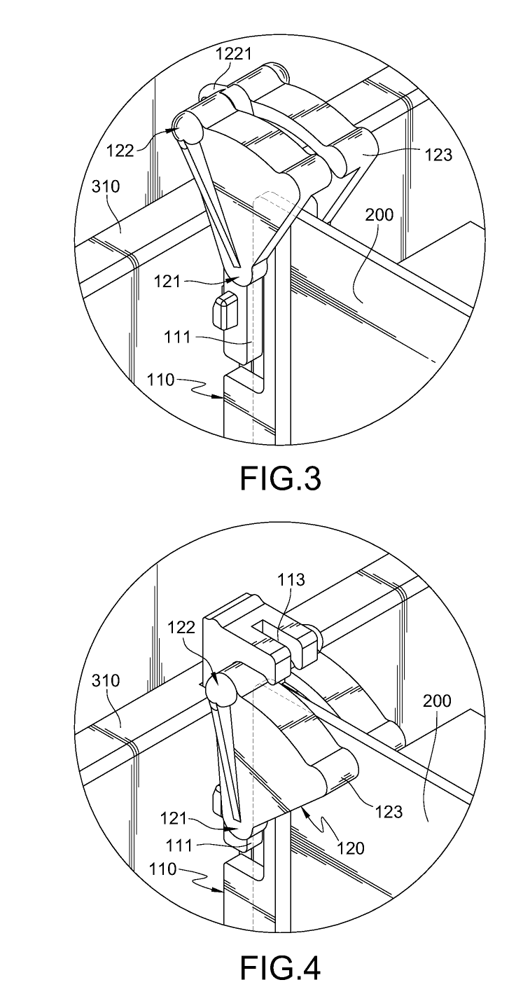

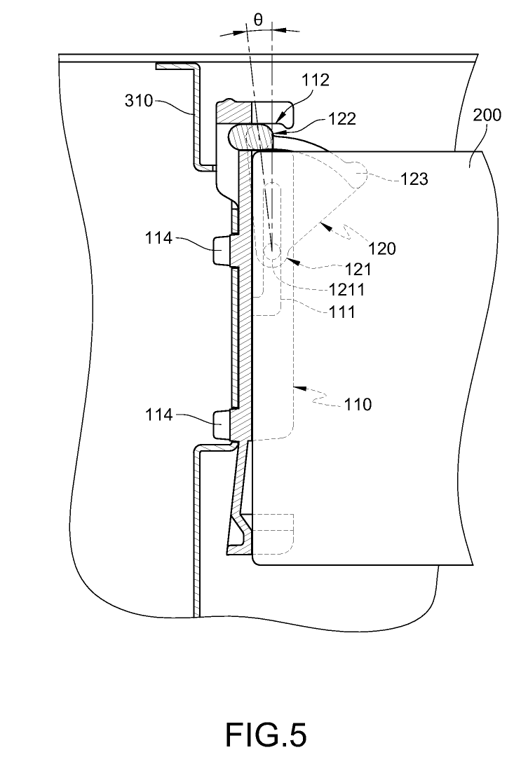

FIGS. 3 to 5 are schematic views of operation states. When the interface card 200 is disposed in the case 310, the pressing member 120 of the interface card fixing device 100 firstly slides above the body 110 along the slide rails 111 and pivotally rotates to a releasing position (that is, the pressing member 120 pivotally rotates upwards relative to the body 110). Then, the stopping portion 1221 bears against the body 110, so as to prevent the pressing member 120 from departing from the releasing position. The interface card 200 enters the guiding slot 113 of the body 110 in a downward mounting direction, and slides to a combination position along the guiding slot 113. The combination position refers to a position at which the interface card 200 is electrically connected to an electrical socket (not shown) in the computer device.

After the interface card 200 slides to the combination position, the pressing member 120 departs from the releasing position, and slides downwards along the slide rails 111. At this time, the pressing end 122 of the pressing member 120 pivotally rotates to a pressing position, and is fixed in the accommodation slot 112 of the body 110 to interfere with the interface card 200 in the mounting direction, so as to press against the interface card 200 to maintain the interface card 200 at the combination position without being loosened or detached. Axial centers of the pressing end 122 and the pivoting end 121 are not located on the same axis, such that the pressing end 122 and the pivoting end 121 form an angle θ, so as to stably press against the interface card 200, thereby ensuring that the pressing member 120 still presses against the interface card 200 under an counter force of the interface card 200.

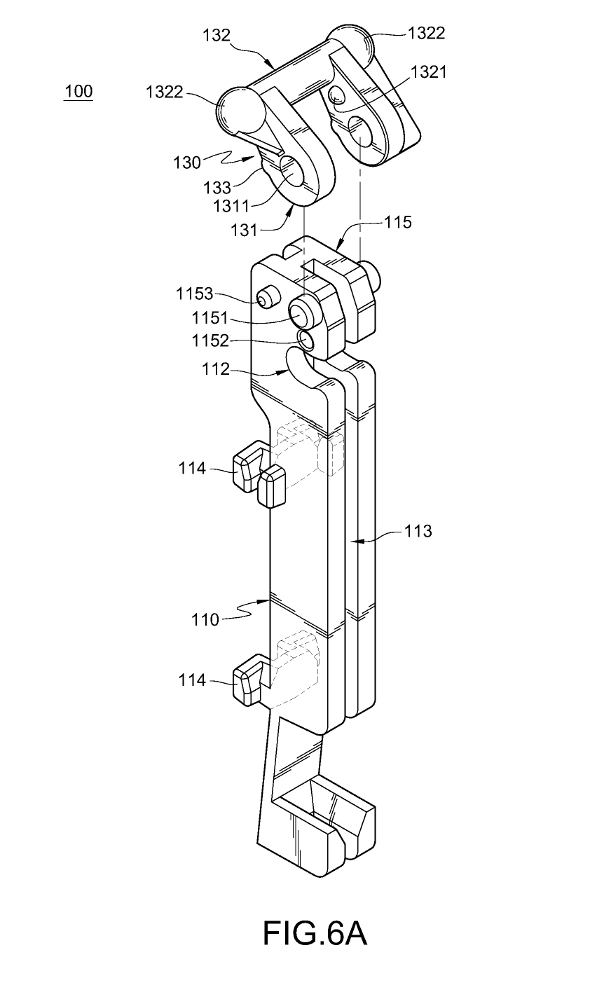

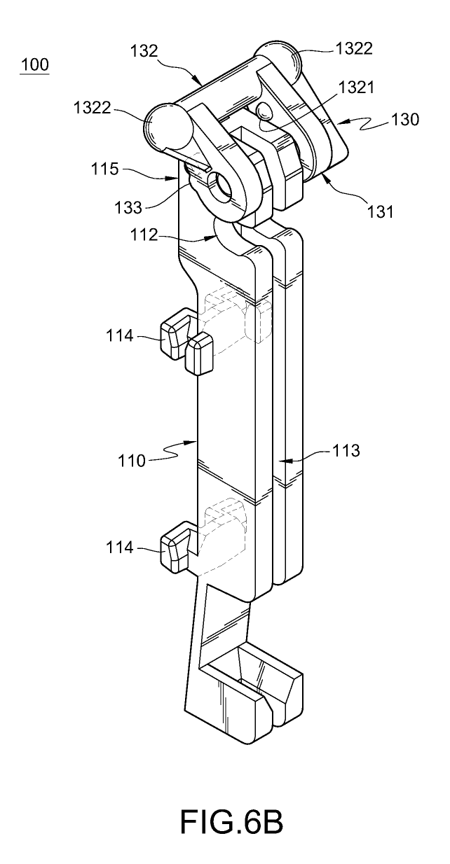

FIGS. 6A, 6B, and 7 are schematic three-dimensional views of a second embodiment of the present invention. An interface card fixing device 100 according to the second embodiment of the present invention is used for fixing an interface card 200 in a case 310 of a computer device 300. A plurality of interface cards 200 may be electrically disposed in the computer device 300, and the number of the interface card fixing device 100 is determined by the number of the interface card 200, such that the interface card fixing device 100 and the interface card 200 are combined in a one-to-one manner.

The interface card fixing device 100 according to the second embodiment of the present invention comprises a body 110 and a pressing member 130. The body 110 is designed as a bar-shaped structure, and has at least two hooks 114 on a side surface thereof. The hooks 114 are fastened into buckling holes 311 of the case 310, such that the body 110 is fixed on the case 310. It should be noted that, persons skilled in the art may also use other methods to combine the body 110 with the case 310, and the present invention is not limited to this embodiment.

Referring to FIGS. 6A and 6B, one end of the body 110 is a first pivoting end 115, and the first pivoting end 115 has an inwardly recessed accommodation slot 112. The body 110 further has a guiding slot 113 crossing the accommodation slot 112 (that is, the guiding slot 113 is disposed along a major axis of the body 110), such that the accommodation slot 112 and the guiding slot 113 are disposed perpendicular to each other. In addition, the first pivoting end 115 further has two opposite first pivot shafts 1151, two opposite positioning holes 1152, and two opposite stopping ribs 1153.

One end of the pressing member 130 is a second pivoting end 131, and the other end of the pressing member 130 is a pressing end 132. Two opposite first pivot holes 1311 are formed on the second pivoting end 131, and the two first pivot shafts 1151 of the body 110 are respectively inserted into the first pivot holes 1311, such that the pressing member 130 is pivotally connected to the body 110. A stopping protrusion 1321 is respectively protruded from two opposite inner wall surfaces of the pressing member 130, two opposite bumps 133 are protruded from the pressing member 130, and a pivotally rotating path of the pressing member 130 causes the bumps 133 to interfere with the stopping ribs 1153 of the body 110. In addition, the pressing end 132 of the pressing member 130 further has two operating portions 1322, such that a user may hold the operating portions 123 to enable the pressing member 130 to pivotally rotate.

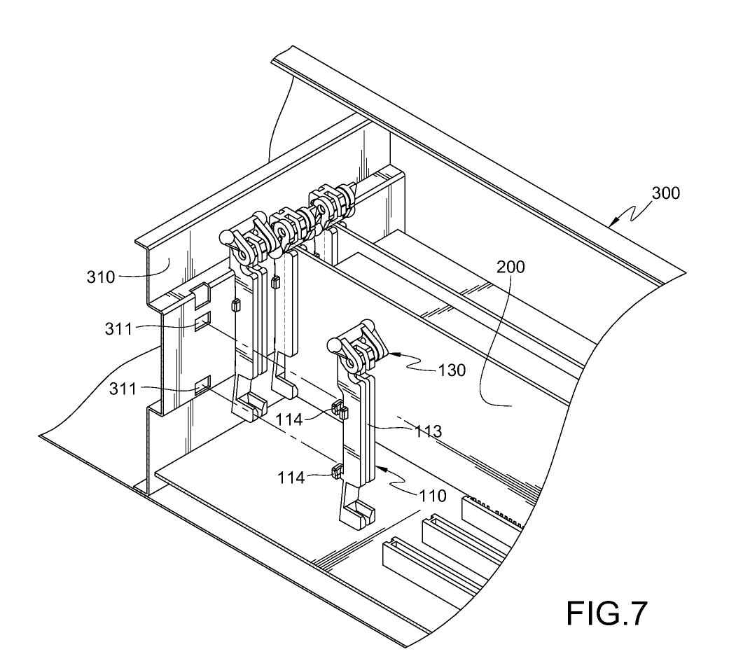

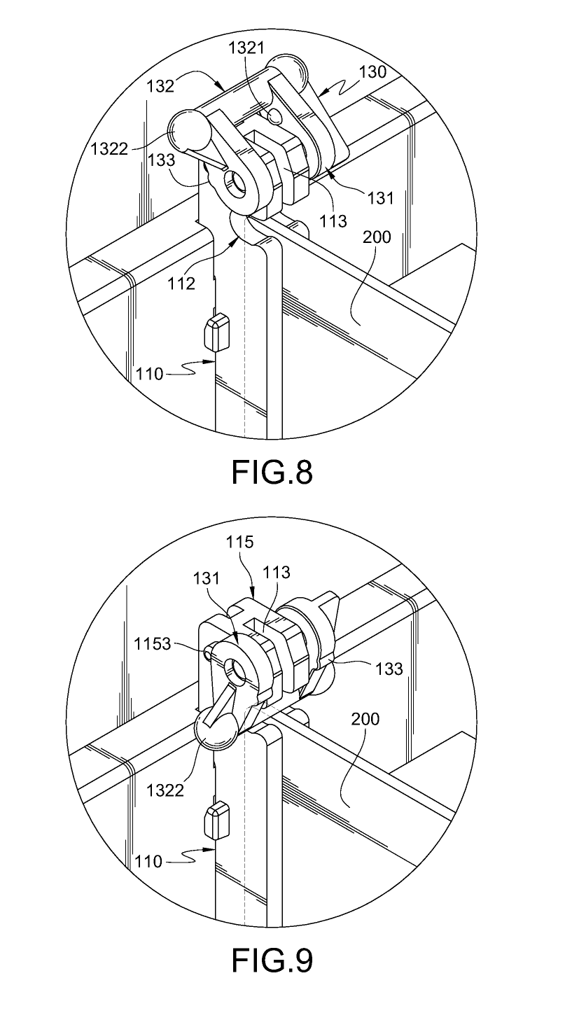

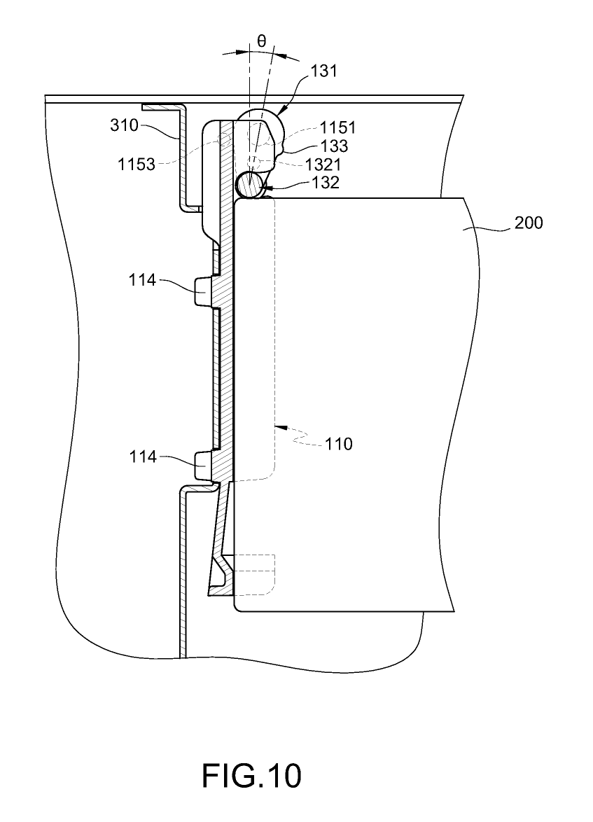

FIGS. 8 to 10 are schematic views of operation states. When the interface card 200 is disposed in the case 310, the pressing member 130 of the interface card fixing device 100 firstly pivotally rotates to a releasing position (that is, the pressing member 130 pivotally rotates upwards relative to the body 110), and the stopping protrusions 1321 bear against the body 110, so as to prevent the pressing member 130 from departing from the releasing position. The interface card 200 enters the guiding slot 113 of the body 110 in a downward mounting direction, and slides to a combination position along the guiding slot 113. The combination position refers to a position at which the interface card 200 is electrically connected to an electrical socket (not shown) in the computer device.

After the interface card 200 slides to the combination position, the pressing end 132 of the pressing member 130 pivotally rotates to a pressing position, and is fixed in the accommodation slot 112 of the body 110 to interfere the interface card 200 in the mounting direction, so as to press against the interface card 200 to maintain the interface card 200 at the combination position without being loosened or detached. Axial centers of the pressing end 132 and the second pivoting end 131 are not located on the same axis, such that the pressing end 132 and the second pivoting end 131 form an angle θ, so as to stably press against the interface card 200, thereby ensuring that the pressing member 130 still presses against the interface card 200 under an counter force of the interface card 200.

When the pressing end 132 of the pressing member 130 pivotally rotates to the pressing position, the bumps 133 of the pressing member 130 interfere with and bear against the stopping ribs 1153 of the body 110. The pressing member is made of a material capable of elastic deformation, and the user needs to apply a small force to force the bumps 133 to pass through the stopping ribs 1153, so as to successfully enable the pressing member 130 to pivotally rotate downwards. The interference between the bump 133 and the stopping rib 1153 provides a clear operating tactile for the user. In addition, when the pressing end 132 of the pressing member 130 pivotally rotates and is fixed in the accommodation slot 112 of the body 110, the stopping protrusions 1321 of the pressing member 130 are embedded into the positioning holes 1152 of the body 110, so as to provide a more effective retention force for the pressing member 130, thereby preventing the pressing end 132 from being loosened or detached from the pressing position due to an external force.

The interface card fixing device according to the present invention can be applied to assemble interface cards to computer devices of different types, and the pressing end of the pressing member interferes with and presses against the interface card to maintain the interface card at the combination position without being loosened or detached. Moreover, the pressing end and the pivoting end of the pressing member form an angle, so as to stably press against the interface card to maintain the interface card at the combination position, thereby preventing the interface card from departing from the combination position due to the counter force thereof or an external force. As such, the interface card is stably disposed on the case without being loosened or detached.

What is claimed is:

1. An interface card fixing device, for fixing an interface card in a case of a computer device, the interface card fixing device comprising:
a body, fixed on the case, and having at least one slide rail, an accommodation slot, and a guiding slot crossing the accommodation slot, wherein the interface card slides within the guiding slot to a combination position; and
a pressing member, wherein one end of the pressing member is a pivoting end and the other end of the pressing member is a pressing end, the pivoting end is pivotally disposed in the slide rail such that the pressing member moves along the slide rail and the pressing end pivotally rotates between a releasing position and a pressing position, the pressing end is fixed in the accommodation slot when the pressing end pivotally rotates to the pressing position, and the pressing end and the pivoting end form an angle, so as to press against the interface card to maintain the interface card at the combination position.

2. The interface card fixing device according to claim 1, wherein the pivoting end has two opposite pivot shafts, the body has two opposite slide rails, and the two pivot shafts are respectively inserted into the two slide rails, such that the pressing member is pivotally connected to the body.

3. The interface card fixing device according to claim 1, wherein the body further has at least one hook, the case has at least one buckling hole, and the hook is fastened into the buckling hole, such that the body is fixed on the case.

4. The interface card fixing device according to claim 1, wherein the pressing end further has a stopping portion, and when the pressing end pivotally rotates to the releasing position, the stopping portion bears against the body.

5. The interface card fixing device according to claim 1, wherein the pressing member further has at least one operating portion.

6. An interface card fixing device, for fixing an interface card in a case of a computer device, the interface card fixing device comprising:
a body, fixed on the case, wherein one end of the body is a first pivoting end, the first pivoting end has an accommodation slot, the body has a guiding slot crossing the accommodation slot, and the interface card slides within the guiding slot to a combination position; and
a pressing member, wherein one end of the pressing member is a second pivoting end and the other end of the pressing member is a pressing end, the second pivoting end is pivotally connected to the first pivoting end, the pressing end pivotally rotates between a releasing position and a pressing position, the pressing end is fixed in the accommodation slot when the pressing end pivotally rotates to the pressing position, and the pressing end and the second pivoting end form an angle, so as to press against the interface card to maintain the interface card at the combination position.

7. The interface card fixing device according to claim 6, wherein the first pivoting end has two opposite first pivot shafts, the second pivoting end has two opposite first pivot holes, and the two first pivot shafts are respectively inserted into the two first pivot holes, such that the pressing member is pivotally connected to the body.

8. The interface card fixing device according to claim 6, wherein the body further has at least one hook, the case has at least one buckling hole, and the hook is fastened into the buckling hole, such that the body is fixed on the case.

9. The interface card fixing device according to claim 6, wherein the pressing member further has at least one stopping protrusion, the first pivoting end has at least one corresponding positioning hole, the stopping protrusion bears against the first pivoting end when the pressing end pivotally rotates to the releasing position, and the stopping protrusion is embedded into the positioning hole when the pressing end pivotally rotates to the pressing position.

10. The interface card fixing device according to claim 6, wherein the pressing end further has at least one operating portion.
